(19) United States
(12) Patent Application Publication
(10) Pub. No.: US 2012/0098392 A1
(43) Pub. Date: Apr. 26, 2012

(54) MOUNTING APPARATUS FOR POWER SUPPLY

(75) Inventors: YUN-LUNG CHEN, Tu-Cheng (TW); LIANG-CHIN WANG, Tu-Cheng (TW)

(73) Assignee: HON HAI PRECISION INDUSTRY CO., LTD., New Taipei (TW)

(21) Appl. No.: 13/104,995

(22) Filed: May 11, 2011

(30) Foreign Application Priority Data
Oct. 25, 2010 (CN) 201010517932.5

(51) Int. Cl. H05K 5/02

(52) U.S. Cl. 312/223.2

(57) ABSTRACT

A mounting apparatus includes a computer case. The computer case includes a bottom plate, a side plate, and a rear plate. A holding portion is located on the side plate. An opening is defined in the rear plate. A resisting panel, a first positioning plate and a second positioning plate extend from the opening for positioning a power supply. The first positioning plate is substantially parallel to the bottom plate, and the second positioning plate is substantially perpendicular to the bottom plate. The resisting panel is attached to the holding portion. The first positioning plate is attached to a top panel of a power supply, and the second positioning plate is attached to a side panel of the power supply.

### BACKGROUND

1. Technical Field

The present disclosure relates to mounting apparatuses, and particularly to a mounting apparatus for securing a power supply to an electronic device.

2. Description of Related Art

A conventional computer system usually includes a power supply unit in a computer case. The installation of the power supply unit in the computer case usually involves the use of screws, which is inconvenient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric, cutaway view of a mounting apparatus in accordance with an embodiment.

FIG. 2 is an isometric view of a rear plate of the mounting apparatus in accordance with an embodiment.

FIG. 3 is similar to FIG. 1, but viewed in a different aspect.

FIG. 4 is an assemble view of FIG. 1.

FIG. 5 is similar to FIG. 4, but viewed in a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

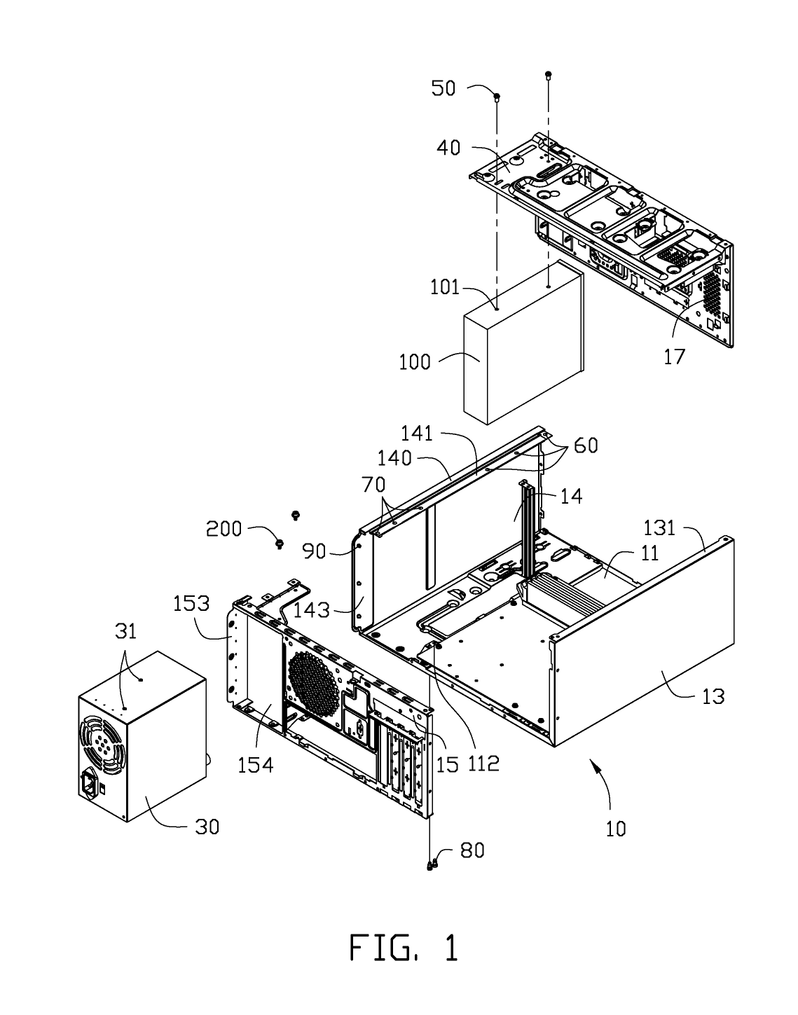

Referring to FIG. 1, a mounting apparatus, according to one embodiment, a power supply 30 with two fixing holes 31, and includes a computer case 10 and a securing member 40. A storage device 100 is secured in the securing member 40, and two holes 101 are defined in the storage device 100.

The computer case 10 includes a bottom plate 11, a first side plate 13, a second side plate 14, a rear plate 15, and a front plate 17 connected to the securing member 40. In one embodiment, the first and second side plates 13, 14 are substantially parallel to each other and perpendicular to the bottom plate 11, and the securing member 40 is substantially perpendicular to the front plate 17.

A protruding piece 112 is located on the bottom plate 11. A flange 131 is connected to the top edge of the first side plate 13. A first flange 410 is connected to the second side plate 14, and a second flange 141 is connected to the first flange 410. A holding portion 143 is located on an end of the second side plate 14.

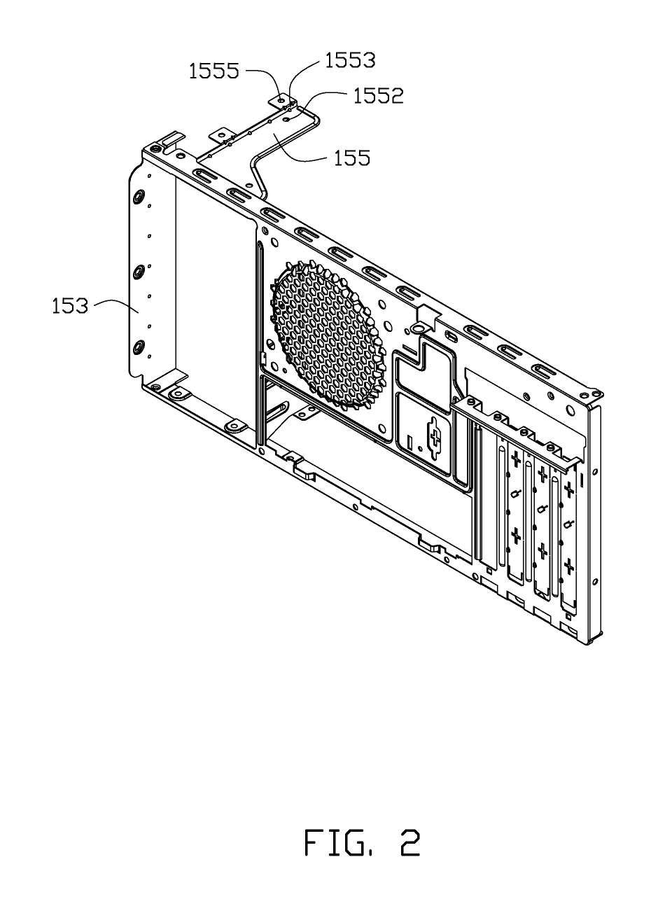

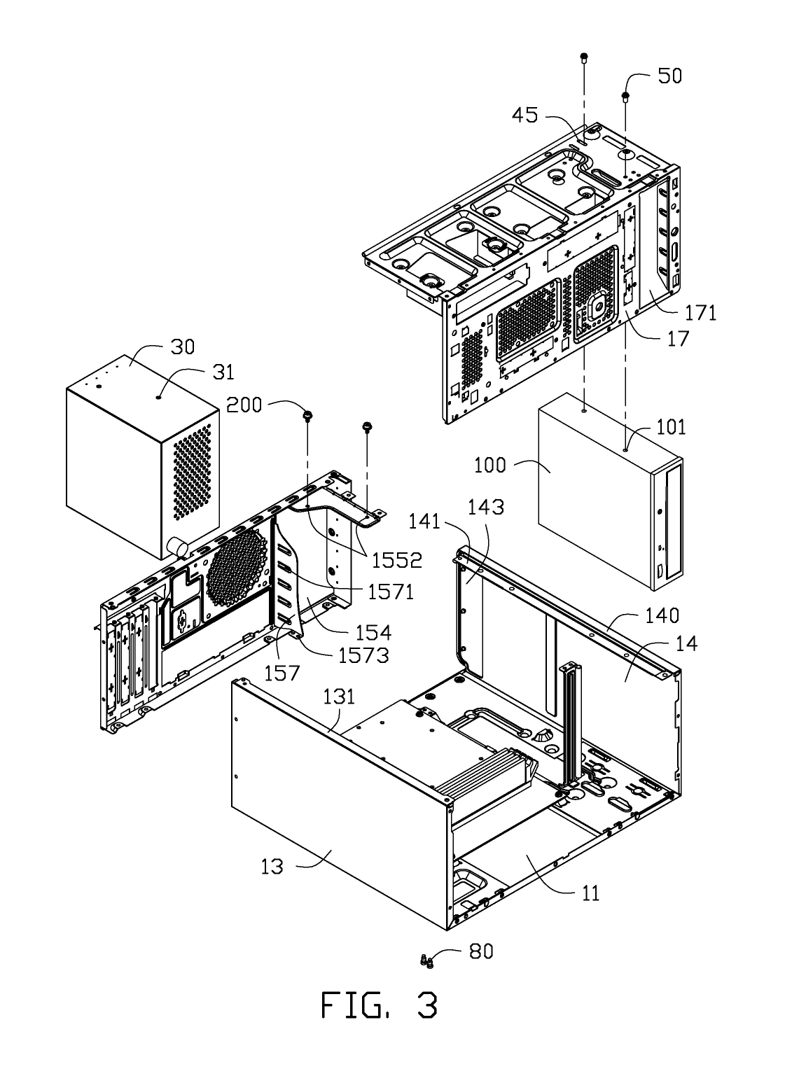

Referring to FIGS. 2-3, an opening 154 is defined in the rear plate 15, and a resisting panel 153 is located near the opening 154, substantially perpendicular to the rear plate 15. A first positioning plate 155, with two mounting holes 1552, is connected to a top edge of the rear plate 15. A pair of securing pieces 1553 is connected to the first positioning plate 155, each securing piece 1553 defines a securing hole 1555. A second positioning plate 157 extends into the computer case 10 and is substantially parallel to the resisting panel 153. A plurality of elastic pieces 1571 is located on the second positioning plate 157 and is arranged on a line perpendicular to the bottom plate 11. A supporting piece 1573 is connected to the second positioning plate 157. In one embodiment, the first positioning plate 155 is substantially parallel to the bottom plate 11; and the second resisting panel 146 is substantially perpendicular to the bottom plate 11.

An access 171 is defined in the front plate 17 and sized so the storage device 100 can pass through. Two mounting holes 45 are defined in the securing member 40, corresponding to the two holes 101 of the storage device 100.

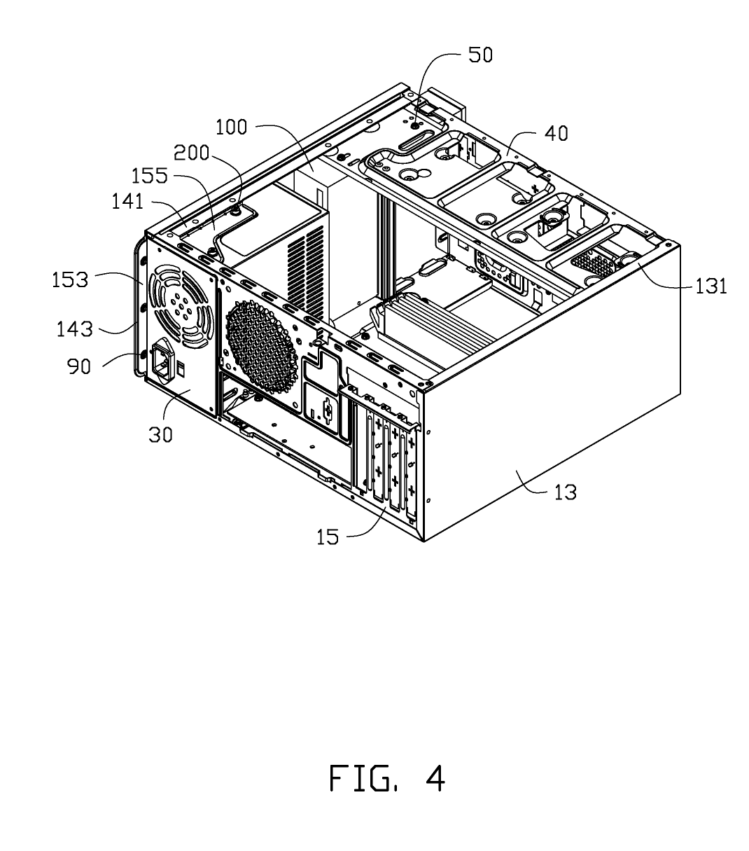

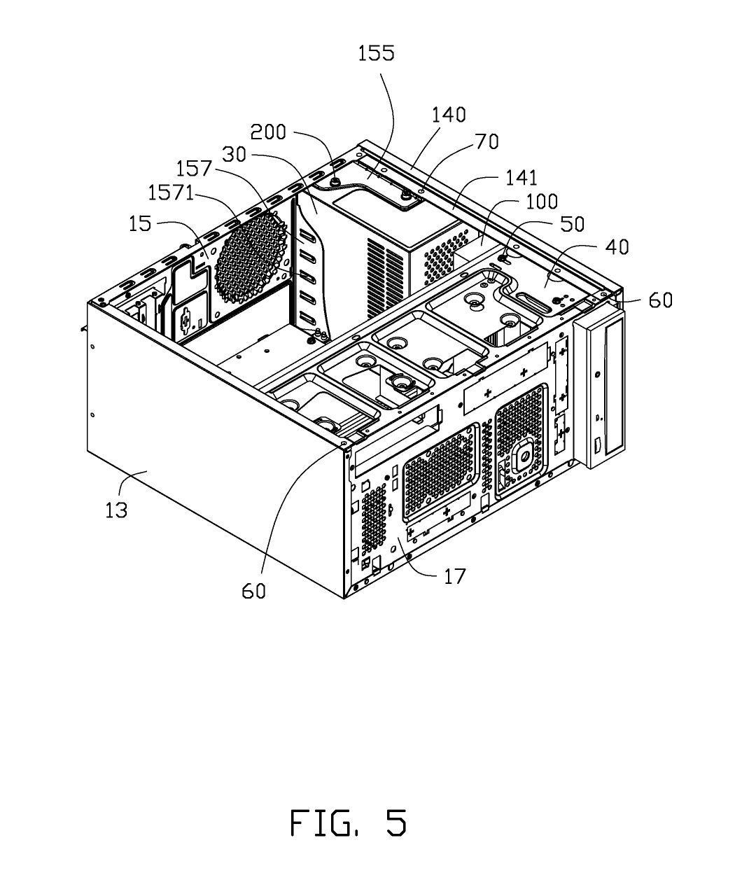

Referring to FIGS. 4-5, in assembly, the front plate 17 is secured to the bottom plate 11 with a known fastening technology, such as jointing or screws. The securing member 40 is secured to the second flange 141 with a plurality of fastening members 60. The rear plate 15 is secured to the bottom plate 11 with a known fastening technology, such as jointing or screws. Then the resisting panel 153 is mounted to the holding portion 143 of the second side plate 14 with three mounting components 90. The first positioning plate 155 abuts the second flange 141, and the two securing holes 1555 align with two holes (not shown) of the second flange 141. Two retaining components 70 are engaged into the two securing holes 1555 and the two holes of the second flange 141, and the first positioning plate 155 are thereby secured to the second flange 141. The supporting piece 1573 is mounted to the protruding piece 112 with a known fastening technology, such as two screws 80.

The storage device 100 passes through the access 171, and the two holes 101 are aligned with the two mounting holes 45. Two fasteners 50 are engaged into the two holes 101 and the two mounting holes 45, to secure the storage device 100 to the securing member 40.

The power supply 30 is inserted into the opening 142 and moved in a first direction, that is perpendicular to the rear plate 15. A first side panel of the power supply 30 abuts the resisting panel 153, a second side panel, opposite to the first side panel of the power supply 30, abuts the second positioning plate 157, and the top panel, of the power supply 30, abuts the first positioning plate 155. The power supply 30 is further moved in the first direction, until the power supply 20 is located between the resisting panel 153 and the second positioning plate 157. The two fixing holes 31 of the power supply 30 are aligned with the two mounting holes 1552 of the first positioning plate 155. Two fixing members 200 are respectively inserted into the fixing holes 31 and the two mounting holes 1552, to mount the power supply 30 to the first positioning plate 155.

In disassembly, the two fixing members 200 are removed from the first positioning plate 155 and the power supply 30. The power supply 30 is moved in a second direction opposite to the first direction, and pulled out from the computer case 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a computer case comprising a bottom plate, a side plate, and a rear plate; the rear plate is connected to the bottom plate and the side plate; a holding portion located on the side plate; an opening defined in the rear plate; a resisting panel, a first positioning plate and a second positioning plate extend from the opening; and the first positioning plate is substantially parallel to the bottom plate, and the second positioning plate is substantially perpendicular to the bottom plate;
wherein the resisting panel is attached to the holding portion, the first positioning plate is adapted to be attached to a top panel of a power supply, and the second positioning plate is adapted to be attached to a side panel of the power supply.

2. The mounting apparatus of claim 1, wherein the second positioning plate is substantially parallel to the resisting panel.

3. The mounting apparatus of claim 1, wherein a protruding piece is located on the bottom plate, and the protruding piece is secured to the second positioning plate.

4. The mounting apparatus of claim 1, wherein the side plate comprises a flange, the first positioning plate comprises a securing piece, and the securing piece is engaged with the flange.

5. The mounting apparatus of claim 1, wherein the second positioning plate comprises a plurality of elastic pieces, and the plurality of elastic pieces is adapted to abut the power supply.

6. The mounting apparatus of claim 1, wherein the computer case further comprises a front plate and a securing member connected to the front plate, and the securing member is adapted to secure a storage device.

7. The mounting apparatus of claim 6, wherein the securing member is substantially perpendicular to the front plate.

8. A mounting apparatus comprising:
a computer case comprising a bottom plate, a side plate, and a rear plate; the rear plate is connected to the bottom plate and the side plate;
a first positioning plate, adapted to be attached to a top panel of a power supply, connected to the side plate and the rear plate; and
a second positioning plate, adapted to be attached to a side panel of the power supply, extending into the computer case;
wherein the first positioning plate is substantially perpendicular to the second positioning plate.

9. The mounting apparatus of claim 8, wherein the side plate comprises a holding portion, and the rear plate comprises a resisting panel attached to the holding portion.

10. The mounting apparatus of claim 9, wherein an opening is defined in the rear plate, the resisting panel extends from the opening and is substantially perpendicular to the rear plate.

11. The mounting apparatus of claim 8, wherein the first positioning plate is substantially parallel to the bottom plate, and the second positioning plate is substantially perpendicular to the bottom plate.

12. The mounting apparatus of claim 8, wherein a protruding piece is located on the bottom plate, and the protruding piece is secured to the second positioning plate.

13. The mounting apparatus of claim 8, wherein the side plate comprises a flange, the first positioning plate comprises a securing piece, and the securing piece is engaged with the flange.

14. The mounting apparatus of claim 8, wherein the second positioning plate comprises a plurality of elastic pieces, and the plurality of elastic pieces is adapted to abut the power supply.

15. The mounting apparatus of claim 8, wherein the computer case further comprises a front plate and a securing member connected to the front plate, and the securing member is adapted to secure a storage device.

16. The mounting apparatus of claim 15, wherein the securing member is substantially perpendicular to the front plate.
